(19) United States
(12) Patent Application Publication
(10) Pub. No.: US 2002/0141228 A1
(43) Pub. Date: Oct. 3, 2002

(54) Low power consumption semiconductor memory

(75) Inventor: Takeshi Fujino, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/028,801

(22) Filed: Dec. 28, 2001

(30) Foreign Application Priority Data
Mar. 27, 2001 (JP) 2001-090271(P)

(51) Int. Cl. G11C 11/24

(52) U.S. Cl. 365/149

(57) ABSTRACT

A twin-cell unit is constituted of two DRAM cells provided on adjacent rows but one row in a row direction, and a bit line pair is constituted of adjacenet bit lines but one bit line coupled to a sense amplifier circuit. One of word lines is driven into a select state. Sense amplifier bands including a plurality of sense amplifier circuits for memory cell data sensing are provided for a plurality of memory arrays each having DRAM cells arranged in rows and columns, and are shared between adjacent memory arrays. Only the sense amplifier circuits in one of sense amplifier bands on both sides of a selected memory arrays are activated. A semiconductor memory stably operating with low consumption power under a low power supply voltage is provided.

### BACKGROUND OF THE INVENTION

1. Field of the Invention

The present invention relates to a semiconductor memory and particularly relates to a low power consumption dynamic random access memory (DRAM) which is stably operated under a low power supply voltage.

2. Description of the Background Art

Static random access memories (SRAMs) have been used as mass storage devices for equipment requiring low power dissipation, such as portable telephones and portable information terminals, in view of high speed operability. Demand rises for the portable equipment of these types to strengthen functions such as the addition of a service as a communication terminal for the Internet. To implement such high functionality, it is necessary to deal with a large amount of data such as image data and audio data and to make the storage capacity of the random access memory contained therein large enough. A 1-bit memory cell of a static random access memory consists of four transistors and two load elements and occupies a large area. If the storage capacity of the memory increases, the area occupied by the memory increases and consumed power increases as well. Thus, consideration has been given to the use of a dynamic random access memory (DRAM) in which a 1-bit memory cell consists of one transistor and one capacitor as a main storage device built in a portable equipment. This is because the memory cell of DRAM occupies a small area, a cost per bit is inexpensive and consumed power is low, compared with an SRAM.

For the above reasons, there is a demand for DRAM's stably operated under a lower power supply voltage with less power consumption. One of techniques for implementing such DRAM's, a group of the inventors of the present invention proposed a twin-cell mode DRAM utilizing two conventional DRAM memory cells for storing a 1-bit data.

FIG. 12 is a diagram showing a conceptual configuration of the conventional twin-cell mode DRAM. In FIG. 12, a twin-cell unit MU storing 1-bit information consists of two DRAM cells 1 and 2. DRAM cell 1 includes a capacitor MQa for storing information and an N-channel MOS transistor (insulated gate type field effect transistor) MTa connecting capacitor MQa to a bit line BL in response to a signal on a word line WLa. DRAM cell 2 includes a capacitor MQb for storing information and an N-channel MOS transistor MTb connecting the capacitor MQb to a bit line /BL in response to a signal on a word line WLb. A common cell plate voltage Vcp is applied to the cell plate nodes of capacitors MQa and MQb. Storage nodes SN and /SN accumulate electric charge according to the stored information.

Bit lines BL and /BL are connected to a sense amplifier 3. Sense amplifier 3 differentially amplifies the voltages of bit lines BL and /BL when made active. In a twin-cell mode, two word lines WLa and WLb are driven into a selected state simultaneously. The storage nodes SN and /SN of DRAM cells 1 and 2 store complementary data. For storage of H data (“1”), storage node SN is set at H level and storage node /SN is set at L level. When storing L data (“0”), storage node SN is set at L level and storage node /SN is set at H level. The H level of each of storage nodes SN and /SN corresponds to an array power voltage Vcca level.

In the twin-cell mode, DRAMI and DRAM 2 of the twin-cell unit are simultaneously connected to bit lines BL and/BL, respectively. Therefore, the voltage difference between bit lines BL and /BL can be set substantially twice as large as that in the case where one normal DRAM cell is connected to the bit line BL or /BL. Accordingly, even with a low array power supply voltage Vcca, if the voltage difference between bit lines BL and /BL is substantially the same as that in a conventional DRAM, the sense amplifier 3 can accurately sense data, to make it possible to decrease the power supply voltage.

Further, since the complementary data are simultaneously read to bit lines BL and /BL, respectively, a refresh interval can be made longer as will be described below.

FIG. 13 schematically represents the voltage changes of the storage nodes of the twin-cell unit with time. In FIG. 13, a cell plate voltage Vcp is at half a voltage level of the array power supply voltage, and bit lines BL and /BL are precharged at half the array power supply voltage, i.e., at Vcca/2 level. Both of the voltage levels of the storage node storing the H data and the storage node storing the L data are lowered by a junction leak current. If data is stored using a conventional 1-bit DRAM cell and the voltage level of the storage node storing H data becomes equal to or lower than the bit line precharge voltage Vcca/2 level, the sense amplifier circuit 3 cannot accurately sense the H data. Therefore, it is required to perform refreshing the data stored in the DRAM cell before the passage of a time Tref at which the level of the stored data becomes equal to or lower than the level of the bit line precharge voltage level.

If the twin-cell unit is employed, by contrast, the storage node storing H data and the storage node storing L data are always coupled to paired bit lines, respectively. Therefore, unless the voltage level of the storage node storing H data becomes lower than the voltage level of the storage node storing L data, accurate sense operation can be ensured. In FIG. 13, therefore, if the voltage difference between bit lines BL and /BL at a time Ta corresponds to the voltage difference equal to or greater than the read voltage ΔV of the conventional DRAM cell, then refresh operation can be performed at time Ta, a refresh interval can be made long enough and a DRAM almost like a refresh-free DRAM can be implemented. As a result, in a standby state such as in a sleep mode, it is possible to significantly decrease the number of times of refreshing of this DRAM, to implement a very low standby current and to reduce consumption power.

Furthermore, even with array power supply voltage Vcca of, for example, 1.2 V and the voltage level of this H data being low, if the voltage difference between bit lines BL and /BL is equal to or greater than the read voltage V of the conventional DRAM cell, accurate sense operation can be ensured. In case of this twin-cell unit, read voltage V is transmitted to bit lines BL and /BL, respectively. Therefore, the voltage difference between bit lines BL and /BL increases to2·ΔV to be substantially twice as great as the read voltage of the conventional DRAM cell. Therefore, if a ratio Cb/Cs of the capacitance Cb of a bit line to the capacitance Cs of a memory cell capacitor is the same as a conventional capacitance ratio, even with array power supply voltage Vcca set at half the conventional voltage level, the same read voltage as the conventional read voltage can be obtained and thus, the sense power supply voltage can be decreased. Conversely, with the array power supply voltage set at an equal level to the conventional array power supply voltage, even if capacitance ratio Cb/Cs (normally about 5) is set to be approximately doubled, i.e., the value of the capacitance Cs of memory cell capacitor MQ (MQa, MQb) is set at half the conventional capacitance value, the same read voltage as the conventional read voltage can be obtained and the DRAM cell can be made small in size.

Consequently, compared with the conventional DRAM storing 1-bit information by1 transistor and1 capacitor, this twin-cell mode DRAM may require an increased area for storing 1-bit information, but can reduce consumed power and decrease power supply voltage. This twin-cell mode DRAM is, therefore, quite a favorable random access memory for a portable equipment such as a pocket telephone or a potable information terminal as stated above. This twin-cell mode DRAM can be used as a single memory chip or as an embedded memory for a system LSI.

FIG. 14 shows one example of the construction of the memory array section of a conventional twin-cell mode DRAM proposed by the inventor et al. of the present invention. The construction of the memory array section shown in FIG. 14 is shown in, for example, Japanese Patent Application No. 2000-195156. In FIG. 14, a sense amplifier band SAB is arranged between memory arrays MAL and MAR. On memory array MAL, bit line pairs BPLa to BPLc and word lines WLLa and WLLb are arranged by way of example. Twin-cell units MU's are arranged corresponding to the crossings between the bit line pairs BPLa to BPLd and the word lines WLLa and WLLb.

On memory array MAR, bit lines BPRa to BPRc and word lines WLRa and WLR b are arranged by way of example. Twin-cell units MU's are arranged corresponding to the crossings between the bit line pairs BPRa to BPRd and the word lines WLRa and WLRb. In these memory arrays MAL and MAR, twin-cell units MU's are arranged in rows and columns. FIG. 14 representatively shows twin-cell units MU's arranged in 1 row by 4 columns in each of memory arrays MAL and MAL.

In sense amplifier band SAB, bit line precharge/equalization circuits 6La and 6Lc are arranged corresponding to bit line pairs BPLa and BPLc, respectively and bit line precharge/equalization circuits 6Rb and 6Rd are arranged corresponding to bit line pairs BPRb and BPRd, respectively. Bit line precharge/equalization circuits are arranged on the other end portion, not shown, of memory cell array MAL in correspondence to bit line pairs BPLb and BPLd, respectively. Bit line precharge/equalization circuit are also arranged on the other end portion, not shown, of memory cell array MAR in correspondence to bit line pairs BPRa ad BPRc, respectively.

Bit line precharge/equalization circuits 6La and 6Lc are activated in response to a bit line equalize instructing signal BLEQL, whereas bit line precharge/equalization circuits 6Rb and 6Rb are activated in response to a bit line equalize instructing signal BLEQR. These bit line precharge/equalization circuits 6La, 6Lc, 6Ra and 6Rd transmit array power supply voltage Vcca onto the respective bit lines of the corresponding bit line pairs when activated. In a standby state, therefore, the bit lines are precharged to the array power supply voltage Vcca level.

Bit line precharge/equalization circuit 6La and 6Lc are coupled to sense amplifier circuits 3a and 3b through bit line isolation gates 7La and 7Lb, respectively. Bit line precharge/equalization circuit 6Rb and 6Rd are coupled to sense amplifier circuits 3a and 3b through bit line isolation gates 7Ra and 7Rb, respectively. Bit line isolation gates 7La and 7Lb are rendered conductive in response to a bit line isolation instructing signal BLIL, whereas bit line separation gates 7Ra and 7Rb are rendered conductive in response to a bit line isolation instructing signal BLIR.

Each of sense amplifier circuits 3a and 3b includes a pair of cross-coupled P-channel MOS transistors, a pair of cross-coupled N-channel MOS transistors, and an N channel MOS transistor for activating the sense amplifier circuit. The common source node of the paired cross-coupled P-channel MOS transistors is coupled to an array power supply node transmitting array power supply voltage Vcca. The common source node of the paired cross-coupled N-channel MOS transistors is coupled to a sense ground node through the sense activating transistor that is rendered conductive in response to a sense amplifier activating signal SAE.

Further, in sense amplifier band SAB, there are arranged a column select gate 8a that is rendered conductive in response to a column select signal CSL0 and couples sense amplifier circuit 3a to local data lines LIO and /LIO, and a column select gate 8b that is rendered conductive in response to a column select signal CSL1 and couples sense amplifier circuit 3b to local data lines LIO and /LIO. Local data lines LIO and /LIO are coupled to global data lines GIO and /GIO, respectively. A column decoder that generates column select signals CSL is arranged corresponding to sense amplifier band SAB, and a column decoder arranged corresponding to a selected memory array is activated to perform decoding operation. Local data lines LIO and /LIO are directly connected through interconnection lines with global data lines GIO and /GIO.

As for the arrangement of the sense amplifier circuits shown in FIG. 14, sense amplifier circuit 3 (3a, 3b) is shared between memory arrays MAL and MAR and arranged corresponding to bit line pairs on every other column in sense amplifier band SAB. The sense amplifier circuits are alternately arranged in the sense amplifier bands on both sides of one memory array.

Now, referring to FIGS. 15 and 16, the data read operation of this twin-cell mode DRAM will be described. First, the operation thereof in reading H data will be briefly described with reference to FIG. 15.

As shown in FIG. 15, in a standby state, bit line equalize instructing signals BLEQL and BLEQR are maintained at a boosted voltage Vpp level. Bit line pairs BPLa, BPLc, BPRb and BPRd are precharged to the array power supply voltage Vcc level by bit line precharge/equalization circuits 6La, 6Lc, 6Rb, and 6Rd. Also, bit line isolation insturucting signals BLIL and BLIR are at the boosted voltage Vpp level, and the bit line pairs are coupled to corresponding sense amplifier circuits 3a and 3b, respectively. When select operation for selecting a memory cell in memory cell array MAL is performed, bit line isolation instructing signal BLIR is driven to a ground voltage level and memory array MAR is isolated from sense amplifier band SAB. At this time, bit line precharge/equalization circuits 6Rb and 6Rd are maintained in an active state. In memory array MAR, therefore, all of bit line pairs BPRa to BPRd are maintained at the array power supply voltage Vcca level.

On the other hand, bit line isolation instructing signal BLIL is held at the boosted voltage Vpp level, bit line equalize instructing signal BLEQL is driven to the ground voltage level, and bit line precharge/equalization circuits 6La and 6Lc complete precharge/equalization operations for bit line pairs BPLa and BPLc. Under this state, the bit line pairs in memory array MAL and sense amplifier band SAB are in an electrically floating state.

Then, row select operation is performed and the voltages of word lines WLa and WLb on memory array MAL rise up to the boosted voltage Vpp level. In reading H data, the voltage level of storage node SN is H level and that of storage node /SN is L level in the twin-cell unit. Therefore, bit lines BL of bit line pairs BPLa to BPLc are maintained at the array power supply voltage Vcca level whereas the voltage level of bit lines /BL lowers. A voltage difference 2·ΔV appearing on these bit lines BL and /BL is represented by the following formula.

2·ΔV=Vcca(1+Cb/Cs).

When memory cell data is read to the bit lines and the voltage difference between the bit lines in pairs is developed enough, then sense amplifier activating signal SAE is driven to H level and sense amplifier circuits 3a and 3b are activated. By the sense operations of the sense amplifier circuits 3a and 3b, bit lines BL are maintained at the array power supply voltage Vcca level and bit lines /BL are discharged to the ground voltage level. These operations are executed on the bit line pairs connected to the twin-cell units storing H data.

Next, referring to FIG. 16, the operation in sensing L data of twin-cell mode DRAM will be described. When storing L data, storage node SN of twin-cell unit MU is at L level and storage node /SN thereof is at H level. The bit line precharge/equalization operation and word line select operation of twin-cell mode DRAM are the same as those when reading H data represented in FIG. 15 as described above. When word lines WLLa and WLLb of memory array MAL are driven into a selected state, the bit line /BL coupled to storage node /SL is maintained at the array power supply voltage Vcca level whereas the voltage level of bit line BL coupled to storage node SN lowers. In this case, the voltage difference 2·ΔV between bit lines BL and /BL is the same as that when reading H data. When reading L data, therefore, bit line /BL is maintained at the array power supply voltage Vcca level whereas bit line BL is discharged to the ground voltage level.

FIG. 17 shows a schematic layout of a memory array. In FIG. 17, element active regions ATR each of an inverse T shape are arranged in rows and column directions. Each element active regions ATR constitutes one layout unit for arranging 2-bit memory cells. Element active regions ATR are arranged to be staggered by two rows between adjacent columns. Bit lines BL and /BL are arranged corresponding to the columns of element active regions ATR. FIG. 17 representatively shows bit lines BL0 and /BL0 to BL3 and /BL3. These bit lines BL0 to BL3 and /BL0 to /BL3 are coupled to element active regions on corresponding columns though bit line contacts BCT, respectively.

Above each element active region ATR, memory cell capacitors CAP are arranged to be opposed with respect to bit line contact BCT. Memory cell capacitors CAP are arranged in alignment in both row and column directions. Memory cell capacitors CAP are coupled to element active regions ATR through capacitor contacts CCT. Capacitor contacts CCT are aligned in row and column directions, similarly to memory cell capacitors CAP. Capacitor contacts CCT are formed on every third row in column direction and formed on every column in row direction. Thus, columns on which bit line contacts BCT are aligned and those on which capacitor contacts CCT are aligned are alternately provided.

Twin-cell unit MU consists of DRAM cells 1 and 2 adjacent each other in row direction. That is, twin-cell unit MU is formed of two DRAM cells 1 and 2 having capacitor contacts CCT adjacent each other in the row direction.

Word lines WL are arranged sandwithing capacitor contacts CCT and bit line contacts BCT therebetween and crossing element active regions ATR. In FIG. 17, word lines WL0 to WL5 are representatively shown and word lines WL on both sides are shown as dummy word lines. An arrangement shown in FIG. 17 is repeatedly arrayed in row and column directions.

In the twin-cell mode, a word line pair WLP constituted of two word lines sandwthing capacitor contacts CAP therebetween is simultaneously activated. Therefor, word lines WL0 and WL1 are simultaneously selected. Likewise, word lines WL2 and WL3 constitute a word line pair WLP and word lines WL4 and WL5 constitute a word line pair WLP.

A sense amplifier circuit 3Ra is arranged for bit lines BL0 and /BL0 and a sense amplifier circuit 3Rb is arranged for bit lines BL2 and /BL2. These sense amplifier circuits 3Ra and 3Rb are aligned in one sense amplifier band.

On the other hand, a sense amplifier circuit 3La is arranged for bit lines BL1 and /BL1 and a sense amplifier circuit 3Lb is arranged for bit lines BL3 and /BL3. These sense amplifier circuit 3La and 3Lb are aligned on another sense amplifier band. Accordingly, sense amplifier circuits 3Ra, 3Rb, 3La and 3Lb are alternately arranged on both sides of a memory array.

In twin-cell mode DRAM, two word lines WL are simultaneously driven into a select state without changing the layout of a memory array of an ordinary, standard DRAM, whereby complementary data are read to paired bit lines BL and /BL. It is, therefore, possible to implement twincell mode DRAM using the memory array layout of ordinary DRAM.

FIG. 18 is a diagram conceptually showing the correspondence between sense amplifier circuits and IO lines transmitting internal data. In FIG. 18, three memory arrays MAa to MAc are shown. Sense amplifier bands are arranged on both sides of memory arrays MAa to MAc in the column direction. Sense amplifier bands SABa and SABb are arranged on both sides of memory array MAa, and sense amplifier bands SABc and SABd are arranged on both sides of memory array MAc. Sense amplifier band SABb is shared between memory arrays MAa and MAb, and sense amplifier band SABc is shared between memory arrays MAb and MAc.

In these sense amplifier bands SABa to SABc, sense amplifier circuits 3 are alternately arranged corresponding to bit line pairs BLP. Column select gates CSG's each coupling a corresponding sense amplifier circuit 3 to an internal data transmission line pair IO in response to column select signal CSL are arranged corresponding to sense amplifier circuits 3's. In this twin-cell mode DRAM, internal data transmission line pairs IO are arranged in common to a plurality of memory arrays, extend over the memory arrays in column direction. In FIG. 18, three internal data transmission line pairs IO0 to IO2 are shown. A predetermined number of sense amplifier circuits 3 are arranged corresponding to each of internal data transmission line pairs IO0 to IO2.

In FIG. 18, two sense amplifier circuits 3 are arranged in one sense amplifier band for one internal data line pair IO. Accordingly, in the arrangement of FIG. 18, four sense amplifier circuits on the sense amplifier bands on both sides of a memory array are arranged for one internal data transmission line pair.

To select one of the four sense amplifier circuits provided for one internal data transmission pair IO, four column select signals CSL<0> to CSL<3> are employed. Here, symbol <> is used to emphasize a signal. These column select signals CSL<0:3> are equivalent to column select signals CSL0 to CSL3 shown in FIG. 14.

Column select signals CSL<0:1>are transmitted through one sense amplifier band and column select signals <3:2> are transmitted through the other sense amplifier band. Accordingly, after data stored in DRAM cells 1 and 2 of twin-cell unit MU is sensed and latched by corresponding sense amplifier circuit 3, sense amplifier circuit 3 in one of the sense amplifier bands on both sides thereof is coupled to corresponding internal data transmission pair IO. In response to column select signals CSL<3:0>, one sense amplifier circuit is selected per internal data transmission line pair and coupled to a corresponding internal data transmission line pair, whereby memory data is transmitted to each of the internal data transmission pair IO.

That is to say, one of column select gates CSG0 to CSG3 is rendered conductive according to column select signals CSL<3:0>and a corresponding sense amplifier circuit is coupled to a corresponding internal data transmission pair.

FIG. 19 is a diagram conceptually showing signal lines charged and discharged in reading memory cell data. FIG. 19 representatively shows driven signal lines when memory array MAb is selected from among four memory arrays MAa to Mad. Row decoders RDa to RDd are arranged corresponding to memory arrays MAa to MAd, respectively. Although column decoders for generating column select signals CSL are arranged corresponding to sense amplifier bands SABb to SABd, respectively, these column decoders are not shown in FIG. 19.

When memory array MAb is selected, it is necessary to isolate memory array MAa from sense amplifier band SABb and to isolate memory array MAc from sense amplifier band SABc. In sense amplifier band SABb, therefore, a bit line isolation instructing signal BLIRa for memory array MAa is discharged to the ground voltage level. In sense amplifier band SABc, a bit line isolation instructing signal BLILc for memory array MAc is discharged to the ground voltage level.

Further, to turn bit line precharge/equalization circuits provided corresponding to respective bit line pairs BLP into an inactive state with respect to selected memory array MAb, both of bit line equalize instructing signals BLEQLb and BLEQRb for this selected memory array MAb are discharged to the ground voltage level. After row select and sense operations, column select operation is performed by the column decoder, not shown, whereby the sense amplifier circuit arranged in one of sense amplifier bands SABb and SABc is coupled to corresponding internal data transmission line pair. When data read is completed, the signals BLIRa, BLILc, BLEQLb and BLEQRb driven to L level are driven again to the boosted voltage Vpp level.

In sense amplifier band SABd, the discharging and charging of signal lines are not carried out since memory arrays MAc and MAd are maintained in a precharge state.

To read data onto internal data transmission line pair IO, therefore, two word lines and all the bit lines on this selected memory array and the bit line isolation instructing signal lines and the bit line equalize instructing signal lines provided on both sides of the selected memory array are driven. Therefore, charging and discharging currents of these signal lines are consumed as operational current in reading data. Here, the data read operation indicates the operation that the sense amplifier circuits sense and latch the data of twin-cell units.

It is now assumed that the interconnection line capacitances of word line WL, bit line BL, bit line isolation instructing signal transmission line transmitting bit line isolation instructing signal BLI and bit line equalize instructing signal transmission line transmitting bit line equalize instructing signal BLEQ are C(WL), C(BL), C(BLI) and C(BLEQ), respectively and that the number of bit lines in one selected memory array is N(BL), then total consumpted electric charges Q(total) per data read operation are represented by the following formula:

Q(total)=2·(C(WL)+C(BLI)+C(BLEQ))·Vpp+(½)·N(BL)·C(BL)·VCCA (1).

Two selected word lines WL are simultaneously driven to the boosted voltage Vpp level and two bit line isolation instructing signal lines are discharged and then charged again to the boosted voltage level. Likewise, after completion of a memory cycle, the bit line equalize isnstructing signal is charged from the ground voltage level to the boosted voltage Vpp level. In addition, half the number of bit lines among bit lines BL and /BL are discharged to the ground voltage level and, after the completion of a memory cycle, precharged again to the array power supply voltage Vcca level.

During this data read operation, even if there occurs consumed electric charges Q(total), ¼ select operation is actually performed by column decoders and only a part of circuits related to power consumption is accessed. In a case of full random access in which a word line is activated for every data access, for example, only the data bits ¼ times as many as data bits sensed by the sense amplifier circuits are used. If power consumed for unused data bits can be reduced, therefore, it is possible to further reduce consumed power.

In other words, during data access, after the sense amplifier bands arranged on both sides of a memory array are made operative to sense and amplify data stored in the twin-cell units, only the sense amplifier circuits on one of the sense amplifier bands are selected. If a consumed current in the unselected sense amplifier band out of those arranged for a selected memory array can be reduced, it is possible to further reduce the current consumed in low consumption power twin-cell mode DRAM.

### SUMMARY OF THE INVENTION

It is an object of the present invention to provide a twin-cell mode DRAM capable of reducing power consumed when writing/reading data or power consumed in operation.

It is another object of the present invention to provide a twin-cell mode DRAM capable of halving consumpted current in operation.

A semiconductor memory according to the present invention includes: a memory array having a plurality of memory cells arranged in rows and columns; a plurality of word lines arranged corresponding to respective rows, and having the memory cells on the corresponding rows connected thereto; a plurality of bit lines arranged corresponding to respective columns, having the memory cells on the corresponding columns connected thereto, and arranged forming pairs; and a row select circuit for driving a word line arranged corresponding to an addressed row into a select state in accordance with an address signal. Two memory cells are arranged for the two word lines and the two bit lines, and the memory cells are arranged so as to be coupled to both of the bit lines forming each pair by one selected word line.

A semiconductor memory according to another aspect of the present invention includes a plurality of memory arrays each having a plurality of memory cells arranged in rows and columns; a plurality of word lines arranged corresponding to the respective rows and having the memory cells on the corresponding rows connected thereto; and a plurality of bit lines arranged corresponding to the columns, having the memory cells on the corresponding columns connected thereto, and arranged forming pairs. Each bit line is arranged extending linearly along a column direction on the corresponding memory array.

The semiconductor memory according to another aspect of the present invention further includes a row select circuit for driving a selected word line arranged corresponding to an addressed row into a select state in accordance with an address signal. The memory cells are arranged in the respective memory arrays such that two memory cells are arranged for the two word lines and the two bit lines and that the memory cells are coupled to both of the bit lines forming a pair by one selected word line.

The semiconductor memory according to another aspect of the present invention further includes a plurality of sense amplifier bands each arranged between the plurality of memory arrays to be shared between adjacent memory arrays. Each of the sense amplifier bands includes a plurality of sense amplifier circuits arranged corresponding to the bit line pairs in the corresponding memory arrays and differentially amplifying potentials of the corresponding bit line pairs when being active.

The semiconductor memory according to another aspect of the present invention further includes a bit line isolation circuit for coupling the bit line pairs in a selected memory array including the selected word line to the sense amplifier circuits in the corresponding sense amplifier band, isolating a first memory array out of first and second memory arrays sharing one sense amplifier band with the selected memory array, from a first sense amplifier band shared between the first memory array and the selected memory array, and coupling the second memory array to a second sense amplifier band shared between the second memory array and the selected memory array, in accordance with the address signal; and a sense control circuit for activating the sense amplifier circuits in the first sense amplifier band, and holding the sense amplifier circuits in the second sense amplifier band in an inactive state, in accordance with the address signal.

By charging and discharging the signal lines only on the sense amplifier band for data access out of the sense amplifier bands provided on both sides of one memory array, it is possible to reduce consumed current by the unselected sense amplifier band, to halve the number of bit lines charged and discharged and to reduce consumed current in operation.

Further, by arranging a bit line of a different bit line pair between one bit line pair and fixing the voltage level of this different bit line pair, it is possible to shield a coupling noise between the bit lines and to insure stable sense operation.

Moreover, by providing two memory cells for the two word lines and two bit lines and arranging the memory cells in correspondence to the crossings between the same word line and the bit line pairs, it is possible to implement a twin-cell mode only by selecting one word line using a conventional memory cell layout, to reduce the number of selected word lines in the twin-cell mode and to reduce consumed current accordingly.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram schematically showing a layout of a memory array of a semiconductor memory according to the present invention;

FIG. 2 shows the connection between one of the memory arrays and a sense amplifier band in the semiconductor memory according to the present invention;

FIG. 3 shows one example of the connection between the other memory array and a sense amplifier band in the semiconductor memory according to the present invention;

FIG. 4 schematically shows the connection between sense amplifier circuits and internal data lines in the semiconductor memory according to the present invention;

FIG. 5 schematically shows driven signal lines when reading data according to the present invention;

FIG. 6 schematically shows the correspondence between respective signals on the sense amplifier band and connected sense amplifier bands in the semiconductor memory according to the present invention;

FIG. 7 shows the correspondence between selected word lines and the connected sense amplifier circuits in the semiconductor memory according to the present invention;

FIG. 8 is a schematic block diagram of a memory mat of the semiconductor memory according to the present invention;

FIG. 9 is a schematic block diagram of a local row control circuit in the semiconductor memory according to the present invention;

FIG. 10 is a schematic block diagram of the control section of a row decoder and of a column decoder in the semiconductor memory according to the present invention;

FIGS. 11A and 11B are schematic block diagrams of the construction of an address interface section;

FIG. 12 is a block diagram of a main part of a conventional twin-cell mode DRAM;

FIG. 13 is a schematic view of the charge holding characteristics of a conventional twin-cell unit;

FIG. 14 is a schematic block diagram of the array section of conventional twin-cell mode DRAM;

FIG. 15 is a signal waveform diagram representing signal waveforms in a case when conventional twin-cell mode DRAM reads H data;

FIG. 16 is a signal waveform diagram representing the operation of the semiconductor memory shown in FIG. 14 in readinf of L data;

FIG. 17 is a diagram showing a schematic layout of a memory arrays in conventional twin-cell mode DRAM;

FIG. 18 schematically shows the connection between sense amplifier circuits and internal data lines in conventional twin-cell mode DRAM; and

FIG. 19 schematically shows driven signal lines in conventional twincell mode DRAM.

### DESCRIPTION OF THE PREFERRED EMBODIMENTS

[First Embodiment]

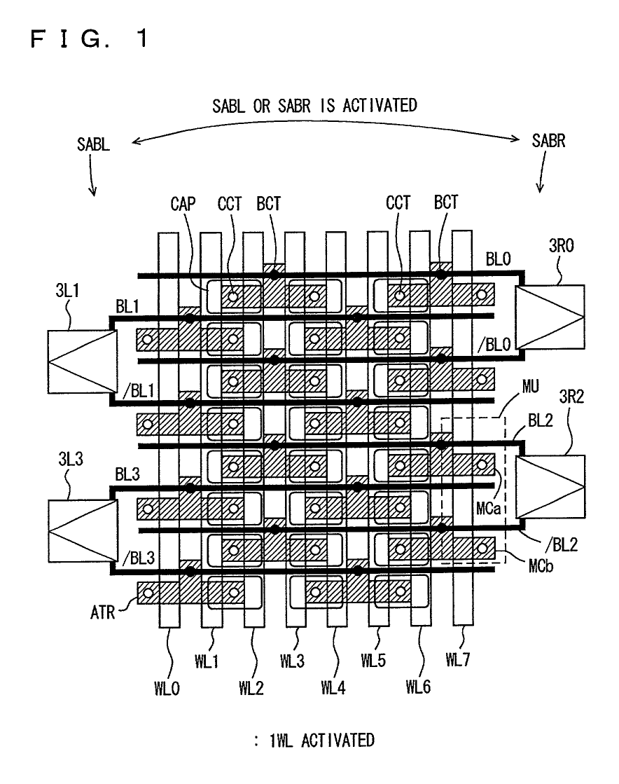

FIG. 1 is a diagram showing a schematic layout of a memory array of a semiconductor memory according to the present invention. In FIG. 1, element active regions ATR's each forming 2-bit memory cells (DRAM cells) are aligned in rows and column directions as in the case of conventional device. Element active regions ATR's are so arranged as to be staggered by two rows between adjacent ATR's. Each element active region ATR has an inverse T shape and connected, at a leg part protruding in the column direction, to a corresponding bit line BL or /BL through a bit line contact BCT. Also, each element active region ATR is connected to a memory cell capacitor CAP through a capacitor contact CCT as in the case of a conventional device. Memory cell capacitors CAP's are aligned in both row and column directions in correspondence to element active regions ATR's. Memory capacitors CAP's are arranged on respective columns in the row direction and arranged on every third row in the column direction.

Bit lines BL's are arranged in pairs. In this embodiment, a pair of bit lines is formed of bit lines arranged with one bit line of another pair interposed in between and coupled to a corresponding sense amplifier circuit. Specifically, bit lines BL0 and /BL0 between which one bit line is arranged are connected to a sense amplifier circuit 3R0, and bit lines BL1 and /BL1 between which bit line /BL0 is arranged are connected to a sense amplifier circuit 3L1. A bit line BL2 adjacent bit line /BL1 forms a pair with a bit line /BL2 arranged on a second adjacent column and the paired bit lines BL2 and /BL2 are connected to a sense amplifier circuit 3R2. A bit line BL3 adjacent to bit line BL2 forms a pair with a bit line /BL3 adjacent thereto but bit line /BL2, and these paired bit lines BL3 and /BL3 are connected to a sense amplifier circuit 3L3.

That is, a bit line forming another pair is arranged between paired bit lines BL and /BL. Word lines WL0 to WL7 are arranged crossing bit lines BL (BL0 to BL3) and /BL (/BL0 to /BL3). In a twin-cell mode, one of word lines WL0 to WL7 is activated. Therefore, differently from the conventional device, a twin-cell unit MU consists of DRAM cells MCa and MCb adjacent each other with one row interposed in between in the row direction. DRAM cells adjacent with each other in row direction are included in different twin-cell units.

In the memory array layout shown in FIG. 1, two DRAM cells MC's are arranged per two word lines WL and two bit lines. Using this so-called “half-pitch arrangement”, a bit line pair is constituted of bit lines arranged on adjacent columns but one column and is connected to a common sense amplifier circuit. In the twin-cell mode, with only one word line selected, DRAM cells MC's are simultaneously coupled to bit lines BL and /BL of a bit line pair and complementary data stored in twin-cell unit MU are read to the paired bit lines. It is, therefore, possible to reduce the number of selected word lines and to reduce consumed current accordingly, in the twin-cell mode.

Sense amplifier circuits 3R0 and 3R2 are included in a sense amplifier band SABR while sense amplifier circuits 3L1 and 3L2 are included in a sense amplifier band SABL. These sense amplifier circuits are alternately arranged on the sense amplifier bands on both sides of a memory cell array, i.e., arranged in a so-called “alternate arrangement type (shared) sense amplifier configuration”.

When one word line WL is selected, DRAM cells having bit line contacts BCT's adjacent to this selected word line WL are selected. Therefore, data stored in twin-cell units MU's are read onto even-number bit line pairs or odd-number bit line pairs. When a word line WL3 is selected, for example, data stored in the DRAM cells are transmitted to bit lines BL0, /BL0, BL2 and /BL2. On the other hand, since the DRAM cells are not coupled to bit lines BL1, /BL1, BL3 and /BL3, bit lines BL1, /BL1, BL3 and /BL3 are maintained at the precharge voltage level. In this case, therefore, sense amplifier circuits 3L0 and 3L2 included in sense amplifier band SABL are maintained in an inactive state and sense amplifier circuits 3R0 and 3R2 included in sense amplifier band SABR are activated. As a result, only one of the sense amplifier bands on both sides of the memory array is activated, so that it is possible to almost halve charging and discharging current during sense operation, compared with that in the construction in which the sense amplifier bands on both sides of the memory array are activated.

Further, by maintaining the unselected sense amplifier band in a precharge state, it is not necessary to drive a bit line precharge/equalize instructing signal and a bit line isolation instructing signal in the unselected sense amplifier band and it is, therefore, possible to further reduce consumed current required to drive these signals. As a result, compared with the construction in which two word lines are simultaneously selected and data stored in twin-cell units are read, consumed current in operation can be greatly reduced.

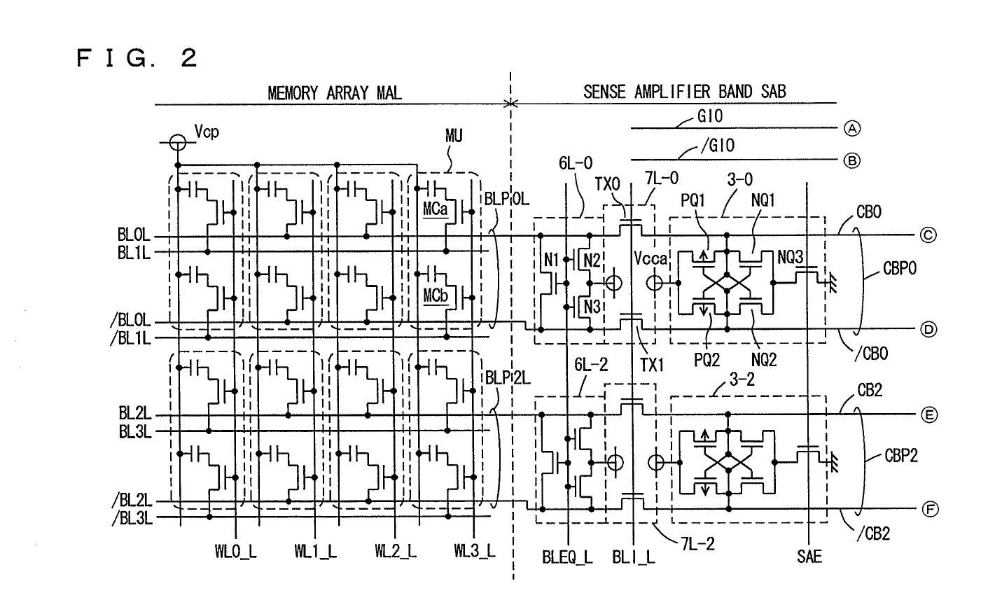

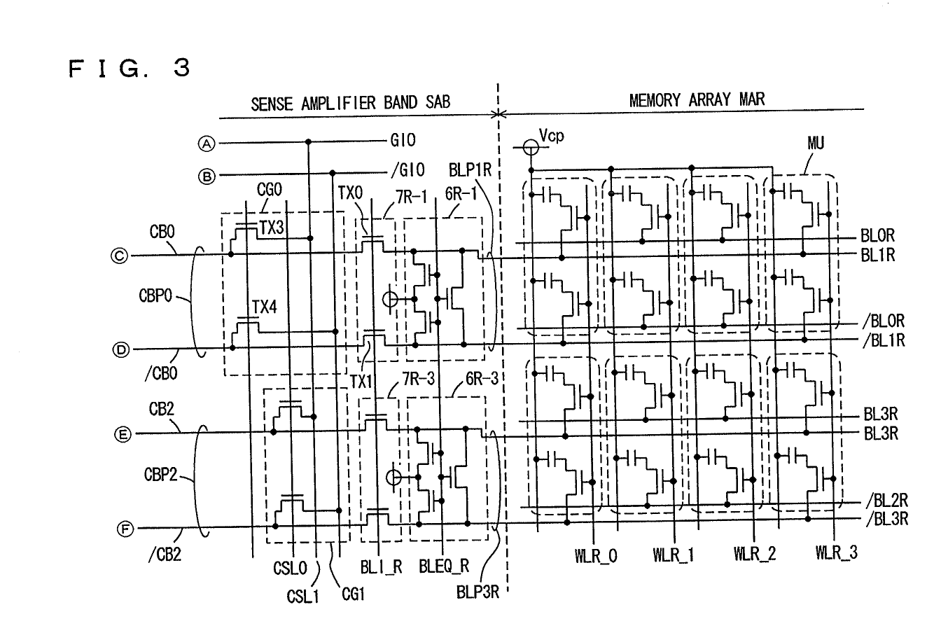

FIGS. 2 and 3 schematically show the connection between a memory array and a sense amplifier band in the first embodiment according to the present-invention. In FIG. 2, a memory array MAL and sense amplifier circuits included in a sense amplifier band SAB are shown. In FIG. 3, the other memory array MAR and column select gates in sense amplifier band SAB are shown.

In FIG. 2, twin-cell units MU's are arranged in a matrix of rows and columns in memory array MAL. Word lines are arranged corresponding to the respective rows of twin-cell units MU's and are connected to the twincell units on corresponding rows. FIG. 2 representatively shows word lines WL0_L to WL3_L.

In column direction, 2-bit DRAM cells are alternately connected to bit lines BL and /BL. This is because a layout unit consists of 2-bit DRAM cells and individual layout units are arranged alternately. DRAM cells MCa and MCb constituting a twin-cell unit MU are coupled to paired bit lines, respectively. FIG. 2 representatively shows bit lines BL0L to BL3L and /BL0L to /BL3L in memory array MAL. A bit line pair BLP0L consists of bit lines BL0L and /BL0L and a bit line pair BLP2L consists of bit lines BL2L and /BL2L.

A bit line BL1L forming another pair is arranged between bit line pair BLP0L and a bit line BL3L forming yet another pair is arranged between bit line pair BLP2L. Likewise, a bit line /BL0L is arranged between paired bit lines BL1L and /BL1L and a bit line BL3L is arranged between paired bit line BL2L and /BL2L. Bit line BL1L, /BL1L and BL3L, /BL3L are coupled to a sense amplifier band (not shown) on the other end of the memory array.

These bit lines are extended linearly and twisted parts for interchanging the positions of bit lines are not provided. By simply using ordinary DRAM cell layout, the correspondence between a sense amplifier circuit and a bit line is changed.

In sense amplifier band SAB, bit line precharge/equalization circuit 6L-0 and 6L-2 activated in response to a bit line equalize instructing signal BLEQ_L are arranged corresponding to bit line pairs BLP0L and BLP2L, respectively. Each of these bit line precharge/equalization circuits 6L-0 and 6L-2 includes N-channel MOS transistors N1 to N3 which is rendered conductive when bit line equalize instructing signal BLEQ_L is activated. N-channel MOS transistor N1 electrically short-circuits the bit lines of the corresponding bit line pair when made conductive. N-channel MOS transistors N2 and N3 transmit array power supply voltage Vcca to the respective bit lines of the corresponding bit line pair when conductive.

Bit line pairs BLP0L and BLP2L are coupled to common bit line pairs CBP0 and CBP2 through bit line isolation gates 7L-0 and 7L-2, respectively. Each of bit line isolation gates 7L-0 and 7L-2 includes transfer gates TX0 and TX1 that are rendered conductive when a bit line isolation instructing signal BL1_L is activated. Sense amplifier circuits 3-0 and 3-2 which are activated, when a sense amplifier activating signal SAE is activated, to differentially amplify the voltages of the corresponding common bit line pairs, are provided for common bit line pairs CBP0 and CBP2, respectively.

Each of sense amplifier circuits 3-0 and 3-2 has the same construction and includes cross-coupled P-channel MOS transistor PQ1 and PQ2, cross-coupled N-channel MOS transistors NQ1 and NQ2 and an N-channel MOS transistor NQ3 that is rendered conductive in response to the activation of sense amplifier activating signal SAE and couples the source nodes of MOS transistors NQ1 and NQ2 to a ground node. The sources of P-channel MOS transistors PQ1 and PQ2 are coupled to a sense power supply node supplying array power supply voltage Vcca.

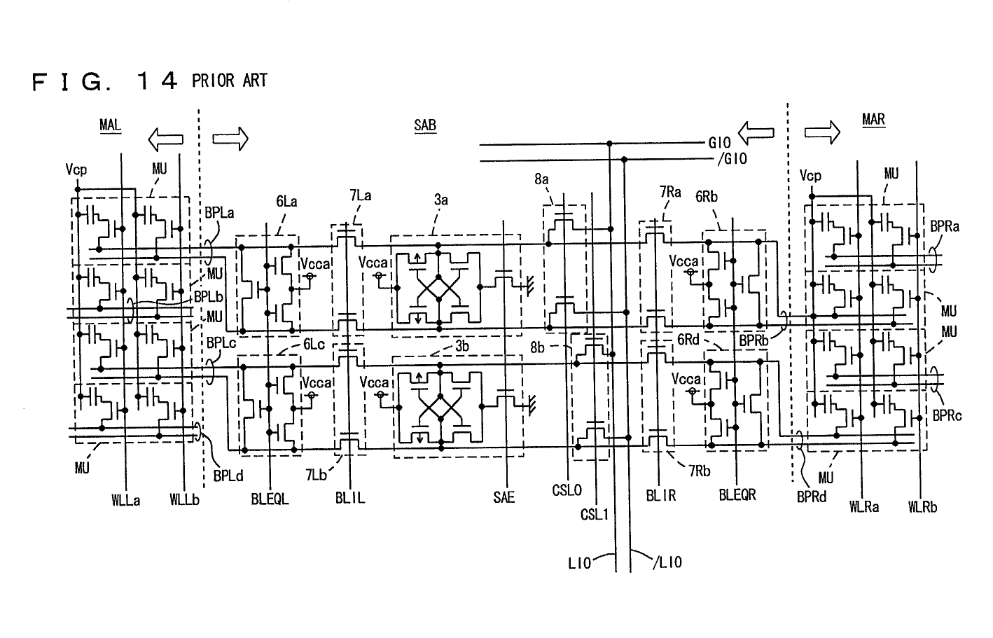

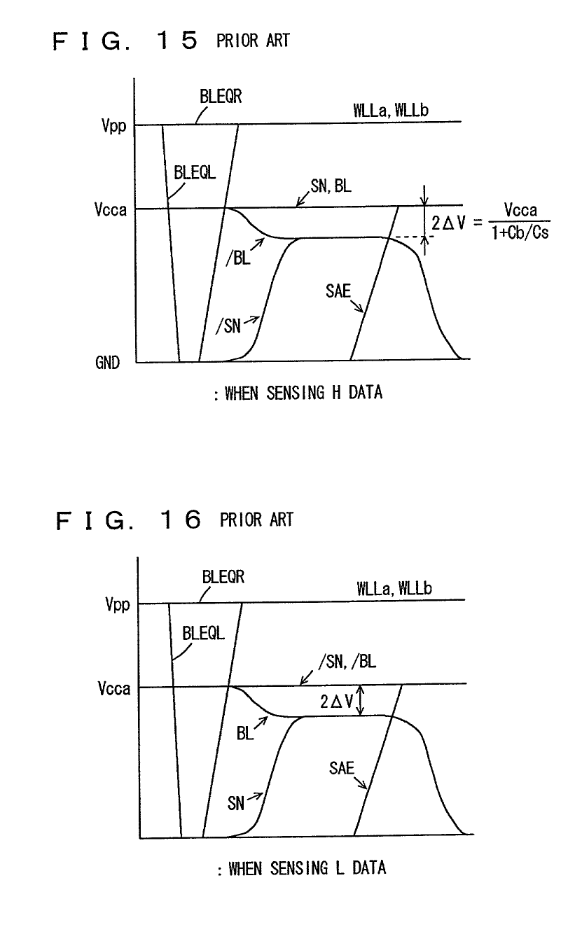

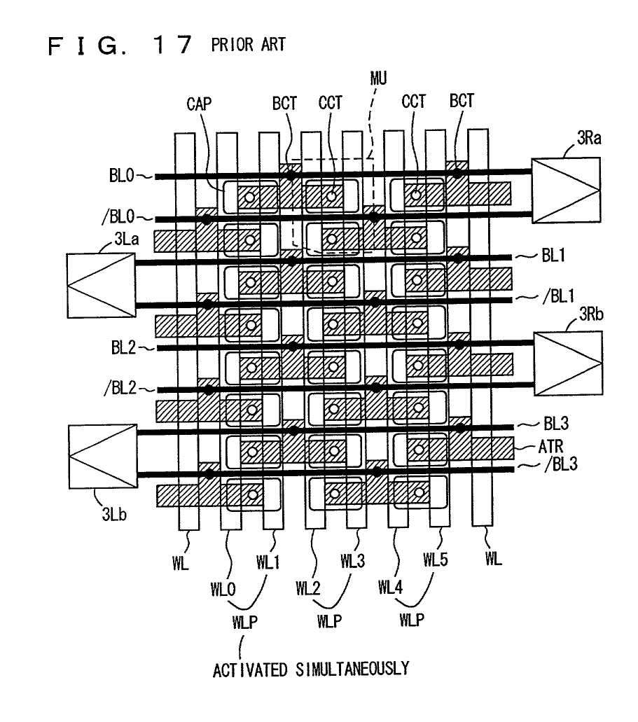

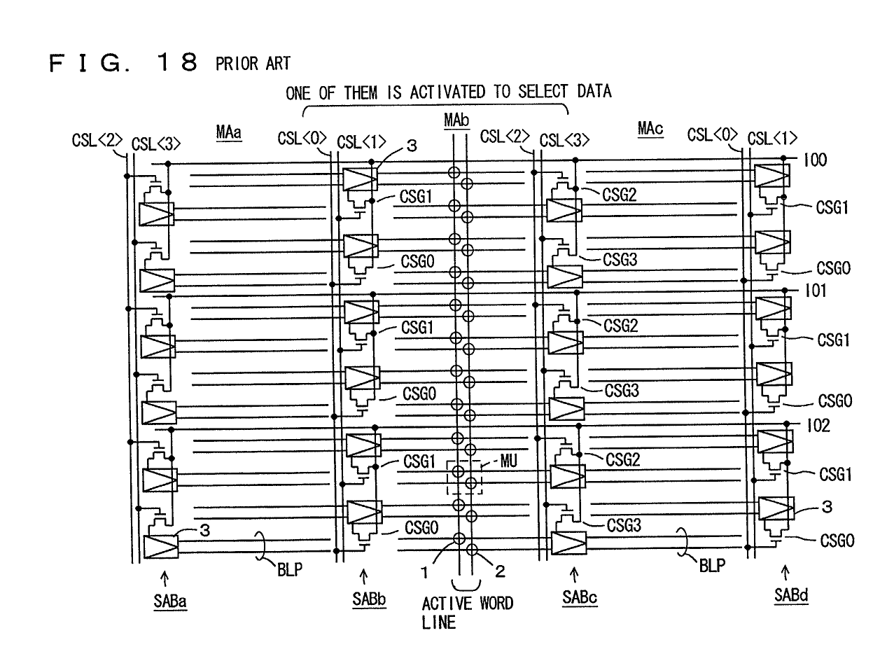

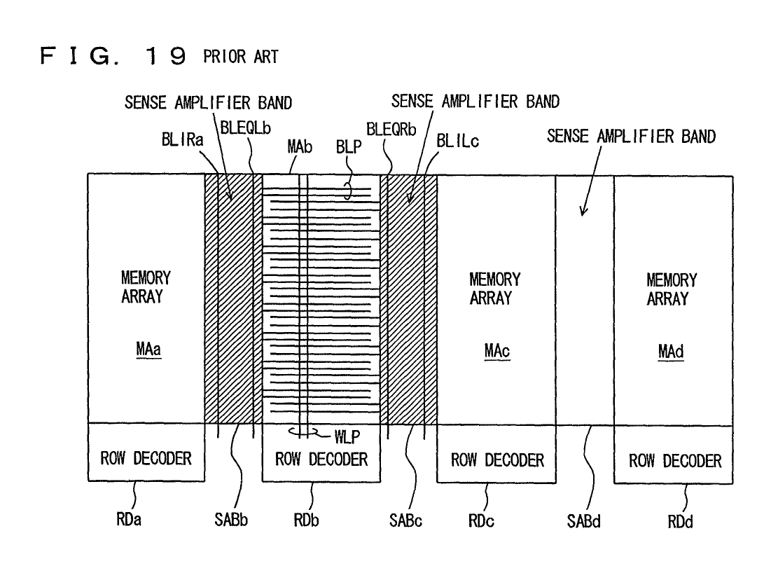

Accordingly, the constructions of memory array MAL and sense amplifier band SAB are the same as those shown in FIG. 14, except for the construction of bit line pairs. The positions of bit lines to which sense amplifier circuits 3 are connected simply differ from those shown in FIG. 14. All the bit lines are extended linearly. The connection between a sense amplifier circuit and bit lines can be easily changed without significantly changing layout.

FIG. 3 shows an example of the constructions of column select gates in sense amplifier band SAB and the other memory array. In FIG. 3, memory array MAR includes twin-cell units MU's arranged in rows and columns, word lines WLR_0 to WLR_3 arranged corresponding to the respective rows of twin-cell units MU's, and bit lines BL0R to BL3R and /BL0R to /BL3R arranged corresponding to the columns of the DRAM cells of twin-cell units MU's. Bit lines BL1R and /BL1R constitute a bit line pair BLP1R and bit lines BL3R and /BL3R constitute a bit line pair BLP3R. While a multiple of twin-cell units MU's and a multiple of bit line pairs BLP_R and word lines WLR are arranged in memory array MAR, FIG. 3 representatively shows the construction of a part related to the twin-cell units arranged in 4 rows by 2 columns. The DRAM cells are coupled to bit lines BLR and /BLR alternately in respective columns in a unit of 2 bits in accordance with the layout units.

Bit line precharge/equalization circuits 6R-1 and 6R-3 are arranged corresponding to bit line pairs BLP1R and BLP3R, respectively. Bit line precharge/equalization circuits 6R-1 and 6R-3 are activated, when a bit line equalize instructing signal BLEQ_R is activated, to precharge and equalize the bit lines of the corresponding bit line pairs to array power supply voltage Vcca level. Bit line pairs BLP1R and BLP3R are coupled to common bit line pairs CBP0 and CBP2 through bit line isolation gates 7R-1 and 7R-3, respectively. Accordingly, bit line pairs staggered by one column in memory arrays MAL and MAR are coupled to common bit line pairs CBP0 and CBP2.

Odd-number bit line pairs in memory array MAL and even-number bit line pairs in memory array MAR are coupled to the sense amplifier circuits in the sense amplifier bands on their respective other ends, not shown, through bit line isolation gates, not shown. In these sense amplifier bands, therefore, the sense amplifier circuits are arranged according to “alternate arrangement type shared sense amplifier” configuration.

When either a word line WLR_0 or WLR_3 is selected in memory array MAR, data stored in twin-cell units MU's are read onto bit line pairs BL1R, /BL1R and BL3R, /BL3R. On the other hand, when a word line WLR_1 or WLR_2 is selected, data stored in twin-cell units MU's are read onto bit line pairs BL0R, /BL0R and BL2R, /BL2R. Accordingly, in FIGS. 2 and 3, if one of word lines WL1_L, WL2_L, WLR_0 and WLR_3 is selected, twin-cell unit data are transmitted to sense amplifier circuits 3-0, 3-2, . . . included in this sense amplifier band SAB and sening operation is performed on the transmitted data.

Since data stored in the twin-cell units are not read onto the bit lines other than the bit line pairs connected to the sense amplifier circuits included in sense amplifier band SAB, these unselected bit lines are maintained in a precharge state. If word line WL1_L is selected in memory array MAL, for example, bit line isolation instructing signal BLI_R is set at L level in sense amplifier band SAB and memory array MAR is isoalted from the sense amplifier circuits on sense amplifier band SAB. Bit line equalize instructing signal BLEQ_R for memory array MAR is maintained in an active state to maintain memory array MAR in a precharge state.

In memory array MAL, when word line WL1_L is selected, twin-cell unit data are not read to bit lines BL1L, /BL1L, BL3L and /BL3L. Therefore, bit lines BL1L, /BL1L, BL3L and /BL3L are maintained in a precharge state. In this sense amplifier band, therefore, bit line isolation instructing signals BLI_R and BLEQ_L are driven to L level, and bit line isolation instructing signal BLI_L and bit line equalize instructing signal BLEQ_R are maintained at the boosted voltage Vpp level. In other words, in this sense amplifier band, the number of driven signal lines can be halved on the basis of that in the construction shown in FIG. 14 and consumed power required to charge and discharge the signal lines can be halved, accordingly.

Common bit line pairs CBP0 and CBP2 are coupled to global data lines GI0 and /GIO through column select gates CG0 and CG1 which are rendered conductive in response to column select signals CSL0 and SCL1, respectively. Only the column select signals provided for an activated sense amplifier band are driven to a select state. Thus, it is not necessary to activate one of 4-bit column select signals CSL<3:0> for selecting one sense amplifier circuit per global select signal pair from the sense amplifier bands on both sides of a selected memory array. A column decoder arranged corresponding to the activated sense amplifier band is activated to perform column decoding operation, and one of 2-bit column select signals CSL<1:0>is driven to a select state. As a result, by activating only one column decoder, consumed power required for column selection can be reduced further.

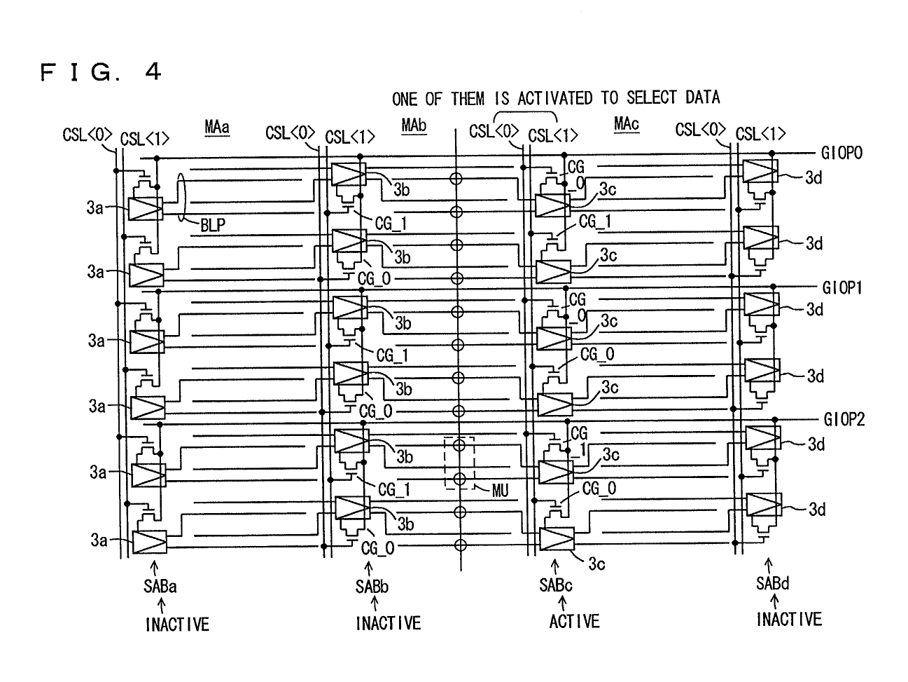

FIG. 4 conceptually shows the connection between sense amplifier circuits and internal data lines. In FIG. 4, sense amplifier bands SABa to SABd are arranged corresponding to memory arrays MAa to MAd. Sense amplifier band SABb is shared between memory arrays MAa and MAb. Sense amplifier band SABc is shared between memory arrays MAb and MAc. Sense amplifier band SABa is shared between memory array MAa and a memory array which is not shown in FIG. 4. Sense amplifier band SABd is shared between memory array MAc and a memory array which is not shown in FIG. 4.

Sense amplifier circuits 3a, 3b, 3c and 3d are provided in respective sense amplifier bands SABa to SABd. An internal data line pair (global data line pair) GI0P is arranged for each two sense amplifier circuits in one sense amplifier band. A set of two sense amplifier circuits is coupled to the corresponding global data line pair through corresponding column select gates and common local data line pair. FIG. 4 representatively shows three global data line pairs GIOP0 to GIOP2.

In each of sense amplifier bands SABa to SABd, 2-bit column select signals CSL<1> and CSL<0> are transmitted. A column select gate CG is arranged corresponding to each sense amplifier circuit 3. These column select gates CG's are selectively made conductive in response to column select signals CSL<1:0>. A sense amplifier circuit is coupled to a corresponding global data line pair when a corresponding column select gate is rendered conductive. In one sense amplifier band, column select gates CG_0 and CG_1 which are rendered conductive in response to column select signals CSL<0> and CSL<1>, respectively, are arranged alternately. The bit line arrangement shown in FIG. 4 differs from that shown in FIGS. 2 and 3 in that bit line pairs in adjacent memory arrays on the same column are coupled to the same amplification circuit. Even with such an arrangement, consumed current can be reduced by activating only one sense amplifier band as in the case of the constructions, as shown in FIGS. 2 and 3, in which bit line pairs in adjacent memory arrays are connected to the same sense amplifier circuit with one column staggered from each other, as will be described later in detail. Here, a construction that bit line pairs in the same column are connected to the same sense amplifier circuit is shown so as to show another possible arrangement of sense amplifier circuits.

Now, consideration will be given to a state in which word line WL in memory array MAb is selected in FIG. 4. Data stored in DRAM cells MC's of twin-cell units MU's connected to this word line WL are read onto the bit line pairs coupled to sense amplifier circuit 3c arranged in sense amplifier band SABc. In this case, therefore, sense amplifier circuits 3c in sense amplifier band SABc are activated. In remaining sense amplifier bands SABa, SABb and SABd, all sense amplifier circuits 3a, 3b and 3d are maintained in an inactive state. When sense amplifier bands SABa, SABb and SABd are in an inactive state, corresponding bit line isolation gates are in a conductive state and bit line precharge/equalization circuits are in an active state. Since memory cell data are not read onto the bit line pairs coupled to sense amplifier band SABb, the bit line precharge/equalization circuits are activated in sense amplifier band SABb. Accordingly, a bit line fixed to a certain voltage level is arranged between each bit line pair to which the data stored in twin-cell units is read. This bit line having the potential fixed functions as one shield against coupling noise between the bit lines, suppresses the influence of noise during sense operation and allows accurate sensing operation.

A column decoder provided corresponding to a selected (or activated) sense amplifier band SABc is activated to activate one of column select signals CSL<0> and CSL<1>. Accordingly, in sense amplifier band SABc, one column select gate of each column select gate pair CG_0 and CG_1 is rendered conductive and corresponding sense amplifier circuits 3c are coupled to corresponding global data line pairs GIOP (GIP0 to GIP0).

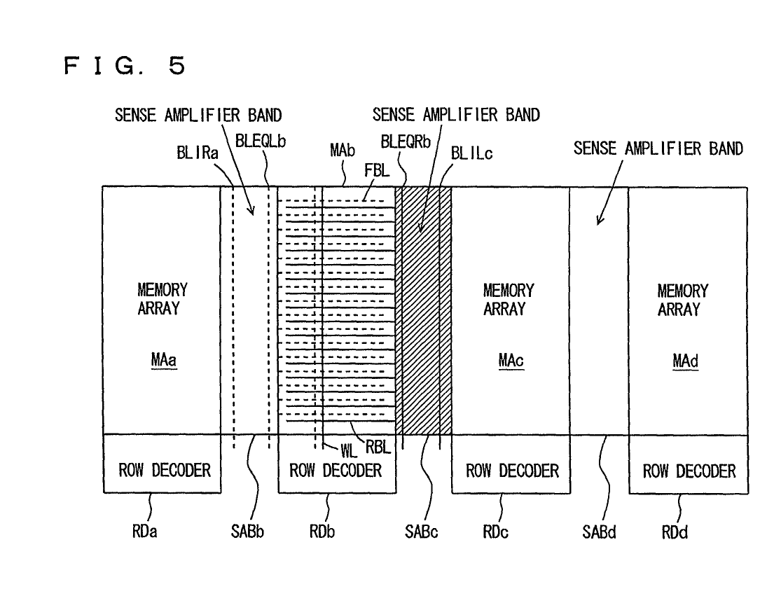

FIG. 5 conceptually shows driven signal lines in the first embodiment according to the present invention. In FIG. 5, memory arrays MAa to MAd are arranged. Row decoders RDa to RDd are provided corresponding to memory arrays MAa to MAd, respectively. A word line WL is selected in memory array MAb. Data stored in the twin-cell units connected to this word line WL are read onto bit lines coupled to sense amplifier band SABc. Even if memory array MAb is a selected memory array, sense amplifier band SABb is maintained in an inactive state. Therefore, memory array MAa is coupled to sense amplifier band SABb in an inactive state. Bit line isolation instructing signal BLIRa for coupling memory array MAa to sense amplifier band SABb is maintained at H level (boosted voltage Vpp level).

Further, the voltage levels of bit lines BL and /BL which are not coupled to selected twin cell units in memory array MAb are fixed to precharge voltage level. In sense amplifier band SABb, therefore, bit line equalize instructing signal BLEQLb for this memory array MAb is maintained at H level. Therefore, these signal lines are not charged/discharged. No signal lines charged/discharged exist in sense amplifier band SABb.

In memory array MAb, bit lines RBL (/RBL) coupled to selected DRAM cells and unselected bit lines FBL (/FBL) having the voltage levels thereof maintained in a precharge state are alternately arranged. Selected bit lines RBL are coupled to sense amplifier band SABc. In memory array MAb, row decoder RDb drives one word line WL to a selected state and maintains the remaining unselected word lines in an unselected state.

In sense amplifier band SABC, the bit line precharge/equalization circuits provided corresponding to selected bit lines RBL (/RBL) in this memory array MAb are inactivated. Therefore, bit line equalize instructing signal BLEQRb for memory array MAb is driven to ground voltage level. In this case, it is necessary to isolate the bit lines in memory array MAc coupled to sense amplifier band SABc, and bit line isolation instructing signal BLILc for this memory array MAc is driven to L level. Sense amplifier band SABd is maintained in an unselected state.

When the sense amplifier circuit senses the data of twin-cell units, one word line, ½ of all the bit lines, one bit line isolation instructing signal BLI and one bit line precharge/equalization signal BLEQ are driven. Accordingly, total consumed electrical charges Q(total) required to read twin-cell unit data once is represented by the following representation:

Q(total)=(C(WL)+C(BLI)+C(BLEQ))·Vpp+N(BL)·C(B)·Vcca/4 (2).

In representation (2), the reason for a coefficient ¼ is given to bit line pairs is that half the bit line pairs of total bit line pairs are coupled to selected twin-cell memory units, only one bit line of each selected bit line pair is discharged and is, after completion of the discharge operation, recovered to original array power supply voltage Vcc level in a memory array.

Therefore, compared with a case of operating the sense amplifier bands on both sides of a memory array, total consumped electrical charges Q(total) are almost half and consumed power can be halved.

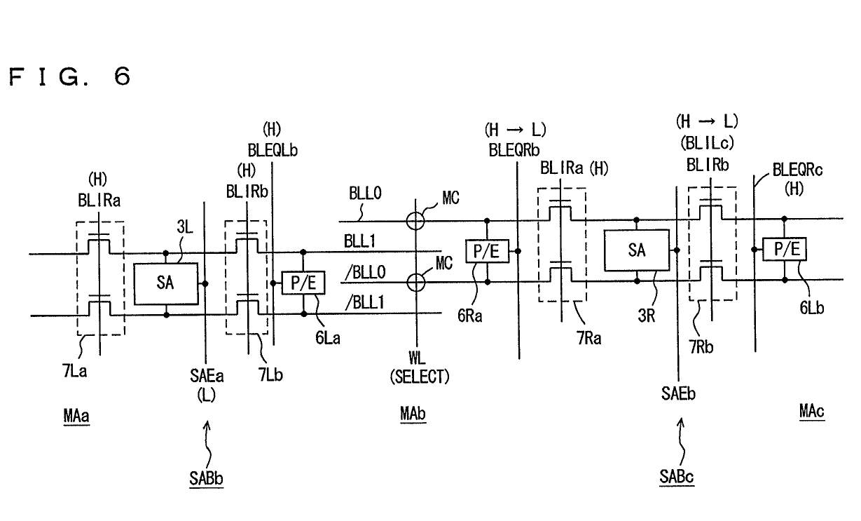

FIG. 6 schematiclly shows the states of respective signals when reading twin-cell unit data. By way of example, FIG. 6 shows a state in which a word line WL is selected in memory array MAb and data of DRAM cells MC are read out onto bit lines BLL0 and /BLL0. In this state, a bit line precharge/equalization circuit (P/E) 6Ra provided for bit lines BLL0 and /BLL0 is required to be set in an inactive state, so that a bit line equalize instructing signal BLEQRb is driven from H level to L level. Since a bit line isolation gate 7Ra is maintained conductive, a bit line isolation instructing signal BLIRa is maintained at boosted voltage level, i.e., H level and bit lines BLL0 and /BLL0 are coupled to a sense amplifier circuit (SA) 3R.

On the other hand, since no data is read to bit lines BLL1 and /BLL1, a bit line precharge/equalization circuit 6La provided for bit lines BLL1 and /BLL1 is maintained in an active state. Therefore, a bit line equalize instructing signal BLEQLb applied to bit line precharge/equalization circuit 6La is maintained at boosted voltage level, i.e., H level, as well. At this time, no problem occurs even if a bit line ioslation gate 7Lb is maintained in a conductive state, and a bit line isolation instructing signal BLIRb is maintained at H level, as well. Bit lines BLL1 and /BLL1 are connected to a sense amplifier circuit 3L. Likewise, no problem occurs even if bit lines in memory array MAa sharing this sense amplifier circuit 3L are connected to a sense amplifier circuit 3L, so that a bit line isolation instructing signal BLIRa is maintained at H level and a bit line isolation gate 7La is maintained conductive. Likewise, a sense amplifier activating signal SAEa is held at L level for sense amplifier circuit 3L. In sense amplifier band SABb, therefore, all the signals are maintained in a standby state.

Meanwhile, since it is necessary to isolate a sense amplifier circuit 3R from the bit lines in memory array MAc, a bit line isolation gate 7Rb is set in a nonconductive state. Accordingly, bit line isolation instructing signal BLIRb is driven from H level to L level. Since a bit line precharge/equalization circuit 6Lb is maintained in an active state in memory array MAc, a bit line equalize instructing signal BLEQRc is maintained at H level. In this state, memory array MAc is isolated from sense amplifier circuit 3R in sense amplifier band SABc and maintained in a precharge state.

In sense amplifier band SABc, therefore, bit line isolation instructing signal BLIRb (BLILc) and bit line equalize instructing signal BLEQRb are driven from H level to L level and sense operation for sensing data stored in the memory cells connected to word line WL is performed. Sense amplifier band SABb is maintained in a standby state (precharge state), so that power consumption in this sense amplifier band SABb can be reduced and consumed current can be reduced accordingly.

Further, as shown in FIG. 6, bit line BLL1 having a voltage level thereof fixed to the intermediate voltage level is arranged between bit lines BLL0 and /BLL0. The same is true for the other selected bit line pairs (bit line pairs connected to memory cells). If a sense amplifier circuit performing sense operation slowly in bit line sense operation exists due to variation in manufacturing process parameters or the like, there is a possibility that data is erroneously read to bit lines connected to the slow sense amplifier circuit by the influence of coupling noise from adjacent bit lines. However, even if such a sense amplifier circuit performing sense operation slowly exists, a bit line which is in a standby state and fixed to the intermediate voltage level is present between charged/discharged bit lines and this bit line in a standby state functions as a shield against coupling noise. As a result, such coupling noise does not occur and stable sense operation can be ensured.

Moreover, a so-called twisted bit line structure in which a crossing part is provided for a bit line pair and “twisted structure” is provided so as to generate a common phase noises on the respective bit lines, has been conventionally adopted to take measures against coupling noise. In this embodiment, by contrast, bit lines away from each other by additional one column form a pair and a bit line between the bit line pair is maintained at precharge voltage level. It is not, therefore, necessary to provide a twisted structure for bit lines and the respective bit lines can be extended linearly. Areas for providing intersection parts between the bit lines are not required and array area can be reduced accordingly. Besides, if crossing parts are provided, the crossing parts are formed into a multilayer structure. In this embodiment, there is no need to provide a multilayer structure for the crossing parts, thereby simplifying manufacturing steps.

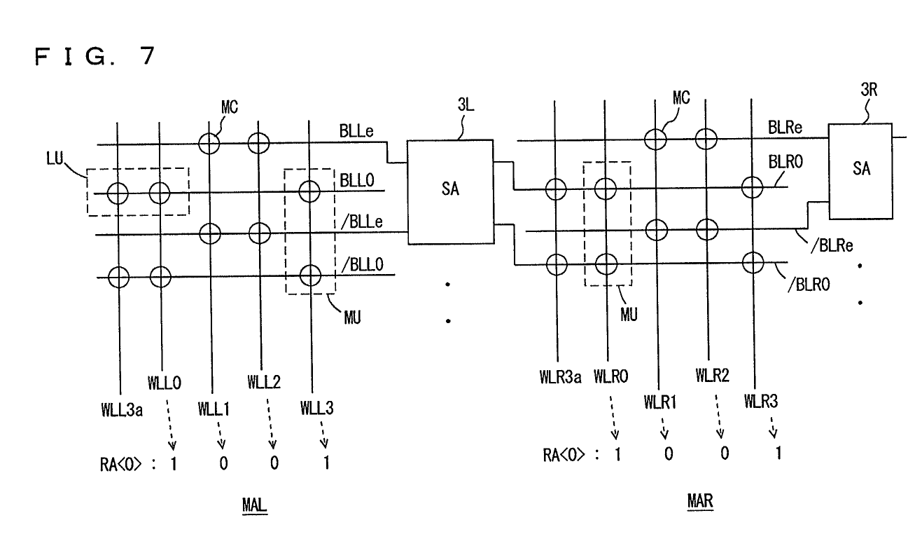

FIG. 7 schematically shows the connection between bit line pairs in memory arrays and sense amplifier circuits. In the arrangement of memory cells (twin cells and DRAM cells) shown in FIG. 7, bit line pairs staggered by one column in adjacent memory arrays are connected to the same sense amplifier circuit (SA).

2-bit DRAM cells MC's adjacent each other in column direction constitute one layout unit LU. Layout units LU's are arranged alternately on the columns in each two columns. Using layout units LU's, it is possible to share a bit line contact between 2-bit DRAM cells. Layout units LU's are arranged on every second column in row direction. When selecting a word line, therefore, twin-cell units MU's are repeatedly arranged with four word lines of WLL0 to WLL3 being one unit.

In memory array MAL, if word lines WLL0 or WLL3 is selected, data stored in twin-cell units MU's are read onto odd-number bit line pairs BLLo and /BLLo. If word lines WLL1 or WLL3 is selected, data stored in twincell units MU's are read onto even-number bit line pairs BLLe and /BLLe. Bit lines BLLe and /BLLe are coupled to a sense amplifier circuit (SA) 3L. Bit lines BLLo and /BLLo are coupled to a sense amplifier circuit, not shown, arranged on the other end of memory cell MAL.

On the other hand, DRAM cells MC's are arranged in the same layout in memory array MAR as that of memory array MAL. Memory arrays MAL and MAR are the same in the arrangement of DRAM cells. Therefore, twin-cell units MU's are repeatedly arranged in column direction with a set of four word lines WLR0 to WLR3 being a unit cycle. In memory array MAR, if word lines WLR0 or WLR3 is selected, data stored in twin-cell units MU's are read onto bit lines BLRo and /BLRo. If word lines WLR1 or WLR2 is selected, data stores in twin-cell units MU's are read onto bit lines BLRe and /BLRe.

In memory array MAR, bit lines BLRo and /BLRo are coupled to sense amplifier circuit 3L and bit lines BLRe and /BLRe are coupled to a sense amplifier circuit 3R. By coupling bit line pairs staggered by one column in adjacent memory arrays to a common sense amplifier circuit, the sense amplifier circuit at the right side in FIG. 7 carries out sense operation if even-number bit lines BLLe and /BLLe or BLRe and /BLRe are selected in memory arrays MAL and MAR. If data stored in the twin-cell units are read onto odd-number bit lines BLLo and /BLLo or BLRo and /BLRo, the sense amplifier circuit at the left of the selected memory array carries out sense operation. It is, therefore, possible for each memory array to detect a sense amplifier band to be connected according to the position of a selected word line in word lines WLL0 to WLL3 and WLR0 to WLR3 set as units.

In this case, the least significant row address bit RA<0> of each of word lines WLL0 and WLL3 is set at “1” and the least significant row address bit RA<0> of each of word lines WLL1 and WLL2 is set at “0” for memory array MAL. Likewise, the least significant row address bit RA<0> of each of word lines WLR0 and WLR3 is set at “1” and the least significant row address bit RA<0> of each of word lines WLR1 and WLR2 is set at “0” for memory array MAR. In case of this correspondence relationship, if the least significant row address bit RA<0> is “1”, the selected memory array is coupled to the sense amplifier band at the left side (or upward) in FIG. 7. Conversely, if the least significant row address bit RA<0> is “0”, the selected memory array is coupled to the sense amplifier band at the right side (or downward) to activate the sense amplifier circuits. With the least significant row address bit RA<0>, only one sense amplifier band can be readily activated selectively.

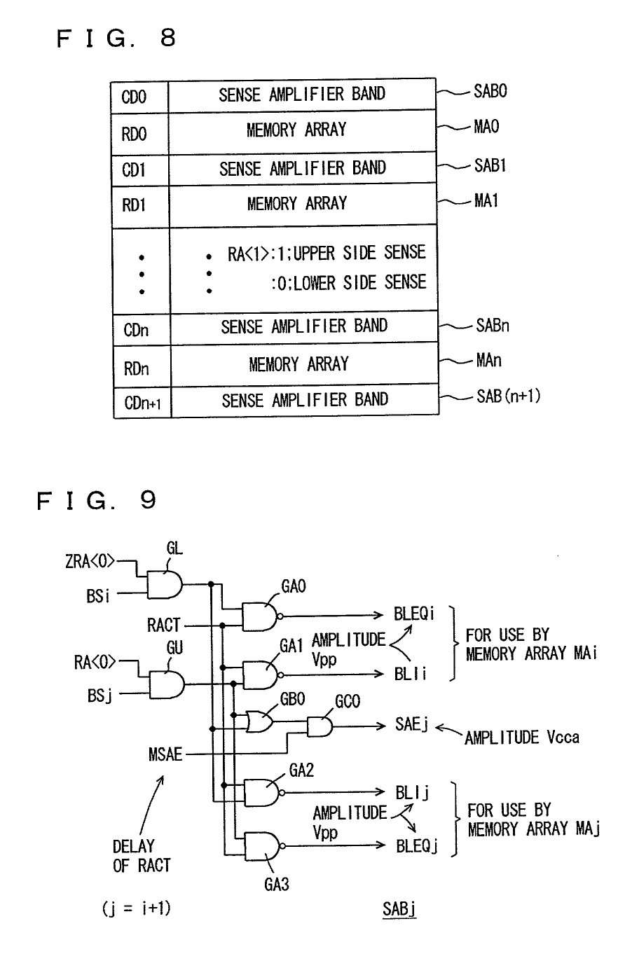

FIG. 8 is a block diagram showing schematically a construction of one memory mat. In FIG. 8, a memory mat is divided into (n+1) memory arrays MA0 to MAn, sense amplifier bands SAB1 to SABn are arranged between memory arrays MA0 to Man, and sense amplifier bands SAB0 and SAB(n+1) are arranged outside memory arrays MA0 and MAn, respectively. Row decoders RD0 to RDn are arranged corresponding to memory arrays MA0 to MAn and column decoders CD0 to CD(n+1) are arranged corresponding to sense amplifier bands SAB0 to SAB(n+1), respectively. The row decoder corresponding to a selected memory array is activated to carry out a row select operation, and one word line in the selected memory array is driven to a select state. According to the value of the least significant row address bit of this selected word line, one of the sense amplifier bands on both sides of the selected memory array (which is a memory array including the selected word line) is activated, and the column decoder provided corresponding to this activated sense amplifier band is activated to carry out a column select operation.

FIG. 9 is a diagram showing a construction of a control circuit for one sense amplifier band. With the construction of a local row control circuit shown in FIG. 9, if row address bit RA<1> is “1” as shown in FIG. 7, the sense amplifier band located at upper side of the selected memory array in FIG. 8 carries out sensing operation. If least significant address bit RA<1> is “0”, the sense amplifier band arranged at a lower side of the selected memory array shown in FIG. 8 carries out sensing operation. The local row control circuit shown in FIG. 9 is provided corresponding to a sense amplifier band SABi. This sense amplifier band SABi is shared between memory arrays SMAi and SMAj, where j=i+1.

In FIG. 9, the local row control circuit includes an AND circuit GL receiving an array select signal BSi specifying a memory array MAi and the inverted value ZRA<0> of the least significant row address bit, an AND circuit GU receiving least row address bit RA<0> and an array select signal BSj specifying the memory array SMAj, an NAND circuit GA0 receiving a row activating signal RACT and an output signal of AND circuit GL and generating a bit line equalize instructing signal BLEQi, an NAND circuit GA1 receiving row activating signal RACT and an output signal of AND circuit GU and generating a bit line isolation instructing signal BLIi, an NAND circuit GA2 receiving row activating signal RACT and the output signal of AND circuit GL and generating a bit line isolation instructing signal BLIj, and an NAND circuit GA3 receiving the output signal of AND circuit GU and row activating signal RACT and generating a bit line equalize instructing signal BLEQj. NAND circuits GA0 to GA3 have a level conversion function and drive bit line isolation instructing signals BLIi and BLIj and bit line equalize instructing signals BLEQi and BLEQj to boosted voltage Vpp level, respectively, if these signals are at H level.

The local row control circuit further includes an OR circuit GB0 receiving the output signals of AND circuits GL and GU, and an AND circuit GC0 receiving the output signal of OR circuit GB0 and a main sense amplifier activating signal MSAE and generating a sense amplifier activating signal SAEi. This sense amplifier activating signal SAEi has an amplitude of array power supply voltage Vcca level and activates sense amplifier circuits provided in corresponding sense amplifier band SABi when being active.

Bit line isolation instructing signal BLIi and bit line equalize instructing signal BLEQi are applied to bit line isolation gates and bit line precharge/equalization circuits provided for memory array MAi, respectively. Bit line isolation instructing signal BLIj and bit line equalize instructing signal BLEQj are applied to bit line isolation gates and bit line precharge/equalization circuits provided for memory array MAj, respectively.

With the construction of the local row control circuit shown in FIG. 9, when memory array MAi is selected, array select signal BSi is rendered active or at H level and array select signal BSj is maintained at L level. At this time, if least significant row address signal bit RA<0> is at H level and a complementary least significant row address bit ZRA<0> is at L level to indicate that a sense amplifier band at upper side of memory array MAi carries out sense operation, the output signal of AND circuit GL is at L level. The output signal of AND circuit GU is maintained at L level since array select signal BSj is at L level. In this state, bit line equalize instructing signals BLEQi and BLEQj and bit line isolation instructing signals BLIi and BLIj are all maintained at boosted voltage Vpp level.

The output signals of AND circuits GL and GU are at L level. Therefore, even if main sense amplifier activating signal MSAE is activated after an elapse of a predetermined time in accordance with the activation of row activating signal RACT, sense amplifier activating signal SAEi from AND circuit GC0 is maintained at L level and no sense operation is carried out. In this state, even if memory array MAi is selected, data stored in twin-cell units connected to a selected word line are not transmitted to sense amplifier band SABi. When sense amplifier band SABi-1 arranged at upperside of memory array MAi carries out sensing operation, sense amplifier band SABi is maintained in a precharge state.

On the other hand, if array select signal BSi is at H level and complementary least significant row address bit ZRA<0> is at H level, it is indicated that sense amplifier band SABj at a lower side of memory array MAi carries out sense operation. Since array select signal BSj is maintained at L level, bit line equalize instructing signal BLEQj from NAND circuit GA3 is maintained at boosted voltage Vpp level, or at H level and memory array MAj is maintained in a precharge state.

The output signal of AND circuit GL attains H level to indicate that the sense operation for memory array MAi is carried out using sense amplifier band SABj. Therefore, the output signal of NAND circuit GA2 attains L level and memory array MAj is isolated from sense amplifier band SABj when row activating signal RACT attains H level. In addition, when row activating signal RACT is raised to H level, bit line equalize instructing signal BLEQi from NAND circuit GA0 attains L level and precharge operation for selected bit line pairs (bit line pairs to which twin-cell units connected to a select word line are coupled) in memory array MAi is completed. Further, since the output signal of AND circuit GU is at L level, bit line isolation instructing signal BLIi is maintained at H level (boosted voltage Vpp level) and memory array MAi is coupled to sense amplifier band SABj.

OR circuit GB0 outputs an H level signal according to the output signal of AND circuit GL. Therefore, if main sense amplifier activating signal MSAE is activated after an elapse of a predetermined time since row activating signal RAC is activated, sense amplifier activating signal SAEj from AND circuit GC0 is activated and sense amplifier circuits in sense amplifier band SABj carry out sensing operation.

If memory array MAj is selected, array select signal BSj attains H level. If least significant row address bit RA<0> is at H level to indicate that sense amplifier band SABj at upper side of memory array MAj is used, then bit line isolation instructing signal BLIi attains L level in response to the activation of row activating signal RACT and memory array MAi is isolated from sense amplifier band SABj. On the other hand, the output signal of AND circuit GL is at L level and bit line isolation instructing signal BLIj is maintained at H level (boosted voltage Vpp level).

As for memory array MAi, the output signal of AND circuit GL is at L level, bit line equalize instructing signal BLEQi is maintained at H level and memory array MAi is maintained in a precharge state. Therefore, sense operation for selected bit line pairs in memory array MAj is carried out by sense amplifier circuits included in sense amplifier band SABj.

As shown in FIG. 7, therefore, if the sense amplifier circuit in the sense amplifier band is coupled to bit line pairs staggered by one column of adjacent memory arrays, it is uniequely determined which sense amplifier band is to be used, upperside sense amplifier band or lower side sense amplifier band, in accordance with the position of a selected word line in memory arrays MA0 to MAn. Thus, a sense amplifier band to be coupled to a selected bit line pair can be readily determined for carrying out sensing operation.

FIG. 10 shows one example of a construction for controlling a row decoder and a column decoder. In FIG. 10, a row decoder RDi provided for memory array MAi is activated when array select signal BSi is activated. Row decoder RDi decodes row addresses RA<m:0> of a predetermined number of bits and drives a word line WL in the corresponding memory array to a select state when activated. On the other hand, a column decoder CDj provided for sense amplifier band SABj is activated when the output signal of OR circuit GB0 of the corresponding local row control circuit (see FIG. 9) attains H level. Column decoder CDj decodes column address bit CA and generates 2-bit column select signals CSL<1:0> when activated. Accordingly, only when the corresponding sense amplifier band is in an active state, this column decoder CDj is activated to carry out decoding operation for column address bit CA, to generate column select signals CSL<1:0> for selecting a column.

It is noted that when a row active command instructing a row select operation is applied, row activating signal RACT is maintained in an active state during this row select operation (until a precharge command is applied). Array select signals BSi and BSj are generated by decoding an array (block) address specifying a memory array included in row address bits RA<m:0> according to the activation of this row activating signal RACT, and are maintained in an active state while row activating signal RAC is active.

By using the constructions shown in FIGS. 9 and 10, it is possible to perform column select operation only in an activated sense amplifier band to couple a sense amplifier circuit arranged corresponding to a selected column to a corresponding global data line pair.

In the case of the arrangement of the bit lines and the sense amplifier circuits shown in FIG. 4, a sense amplifier circuit is shared between bit lines on the same column of adjacent memory arrays. In this case, the position of a sense amplifier band to be used is changed in accordance with the position of a selected memory array. When the position of the sense amplifier band to be used differs according to the position of a selected memory array, the position of the sense amplifier band to be used differs according to whether the selected memory array is an even-number memory array or an odd-number memory array.

In the construction shown in FIG. 9, therefore, least significant row address bits ZRA<0> and RA<0> specifying a memory array to be used are exchanged between the odd-number memory array and the even-number memory array. Such exchange allows only one sense amplifier band to be accurately activated even in the construction that the sense amplifier band to be used is an upper side sense amplifier band or a lower side sense amplifier band in accordance with the position of a selected memory array.

In the construction shown in FIG. 9, for example, when memory array MAi uses the lower side sense amplifier band when least significant row address bit RA<1> is “1” and uses the upper side sense amplifier band when least significant row address bit RA<1> is “1”, complementary least significant row address bit ZRA<0> has only to be applied to AND circuit GL, in place of least significant row address bit RA<0>.

Conversely, in the construction shown in FIG. 9, when memory array MAi uses the lower side sense amplifier band SABj when least significant row address bit RA<0> is “0” and uses upper side sense amplifier band SABi when least significant row address bit RA<0> is “1”, it is sufficient that complenmentary least row address bit ZRA<Q> is applied to AND circuit GL and least significant row address bit RA<0> is applied to AND circuit GU.

If the position of the sense amplifier band to be used differs according to the position of a selected memory array, sense amplifier bands to be used for the respective memory arrays can be easily programmed with interconnection lines transmitting least significant row address bits.

The correspondence between the bit value of least significant row address bit RA<1> and the sense amplifier band to be used may be set opposite to that shown in FIG. 7. If 2-bit least significant row address (0, 0), (0, 1), (1, 0) and (1, 1) are allotted to word lines WL0 to WL3 serving as a layout unit, respectively, the 2-bit least significant row address may be decoded using an EXOR circuit and the decoding result may be applied to AND circuits GL and GU shown in FIG. 9 in place of least significant row address bits RA<0> and ZRA<0>.

If this EXOR circuit is used, the output signal of the EXOR circuit attains L level (“0”) when word line WL0 or WL3 is selected and attains H level (“1”) when word line WL1 or WL2 is selected. Accordingly, it is possible to specify the position of the sense amplifier band to be used based on the logical level of the output signal of this EXOR circuit.

With the construction of the connection between the sense amplifier circuits and the bit lines as shown in FIG. 7, if the output signal of the EXOR circuit is at H level, then the sense amplifier band to be used is the lower side sense amplifier band, and if the output signal of the EXOR circuit is at L level, the sense amplifier band to be used is the upper side sense amplifier band. Therefore, the output signal of the EXOR circuit can be used in place of least significant row address bit ZRA<0> and the inverted signal of the output signal of the EXOR circuit can be used in place of least significant row address bit RA<0>. In this case, an EXNOR circuit may be used as a decoding circuit. The output signal of the EXOR circuit can be employed for the construction that the position of the sense amplifier band to be used is changed according to the position of the selected memory array.

Furthermore, in the above-stated construction, the bit lines are precharged to array power supply voltage Vcca level. The precharge voltage level of the bit lines may be set at a voltage level of half the array power supply voltage Vcca level, i.e., may be set at a Vcca/2 voltage level. It is also possible that the bit line precharge voltage is at ground voltage level. If the bit lines are precharged to ground voltage level, the common source node of the cross-coupled N-channel MOS transistors is coupled to the sense ground node and the common source node of the cross-coupled Pchannel MOS transistors is coupled to the sense power supply node through the sense amplifier activating transistor.

It is further possible that a selected word line is driven to peripheral power supply voltage Vcch level, rather than boosted voltage Vpp level.

Moreover, the global data line pair may be separated into a read global data line pair for transmitting read data and a write global data line pair for transmitting write data. With the internal separated IO construction, a read column decoder for a differential amplification type read select gate connecting a selected bit line pair to a read global data line pair and a write column decoder for a write select gate connecting a selected bit line pair to a write global data line pair are provided separately in each sense amplifier band. The read column decoder or the write column decoder is activated only for the activated sense amplifier band. Since cross-coupled type sense amplifier circuits are arranged in the the separated IO construction, the above-stated construction can be used for controlling the sense amplifier bands for this separated IO construction.

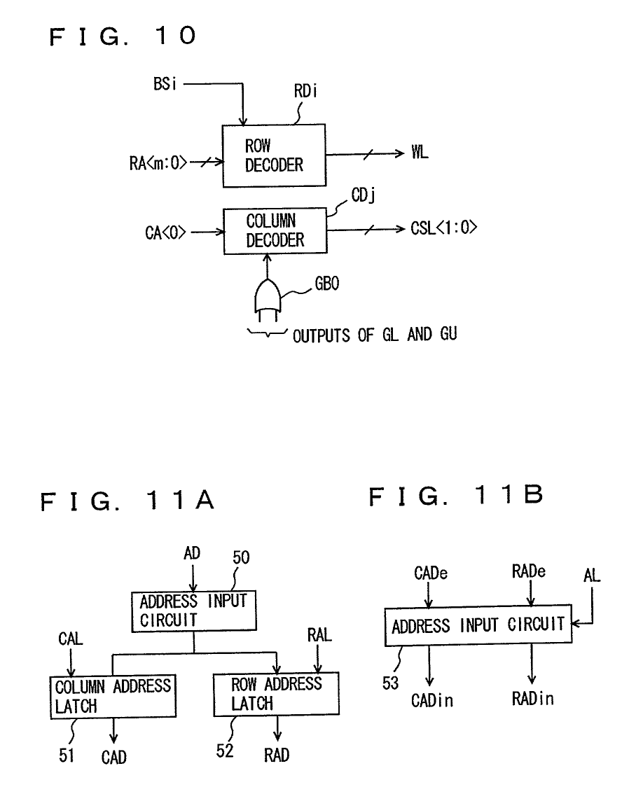

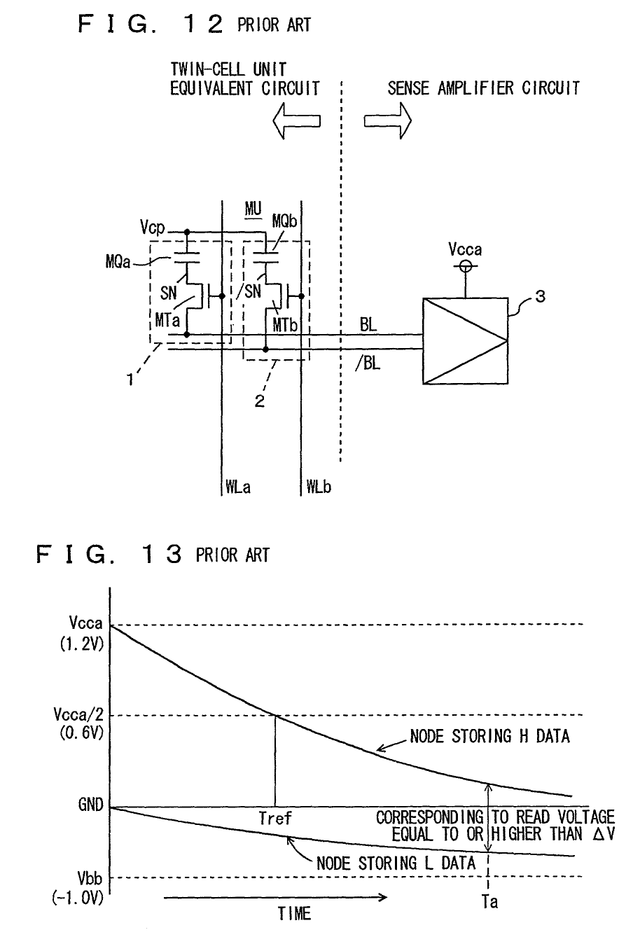

FIG. 11A is a schematic block diagram of an address input section. In FIG. 11A, a row address and a column address are applied, as an address signal AD, to an address input circuit 50 time-division multiplexedly. Internal address signals from address input circuit 50 are applied to a row address latch 52 and a column address latch 51, respectively. Column address latch 51 latches the internal address signal from address input circuit 50 in accordance with a column address latch instructing signal CL and generates an internal column address signal CAD. Row address latch 52 latches the internal address signal from address input circuit 50 in accordance with a row address latch instructing signal RAL and generates an internal row address signal RAD. Row address latch instructing signal RAL is activated for a predetermined period in response to the activation of row activating signal RACT. Column address latch instructing signal CAL is activated when a column select instruction (column access command) is applied.

FIG. 11B shows another construction of an address input circuit. In FIG. 11B, external row and column address signals RADe and CADe are simultaneously applied to an address input circuit 53. Address input circuit 53 latches these external address signals CADe and RADe in accordance with a latch instructing signal AL and generates an internal column address signal CADin and an internal row address signal RADin. In the construction that a row address and a column address are applied non-multiplexedly, it is possible to make an internal column select start timing faster to allow high-speed access.

In the construction that only one sense amplifier band is activated in the alternate arrangement type shared sense amplifier circuit configuration, if a row address and a column address are inputted separately in a timedivision multiplexedly according to an address multiplexing system (see FIG. 11A), the storage capacity (page size) accessible through change of only the column address is halved. However, in case of a full random access system in which only one column address is accessed for one row address, and inaddition, in the case where the row address and the column address are simultaneously inputted to perform an accessing operation as shown in FIG. 11B, there is no need to access a memory cell on an unnecessary column address. Thus, it is possible to sufficiently enjoy an advantage of reducing power consumption.

In the above description, 2-bit column select signals CSL<1:0> are generated for one sense amplifier band. Alternatively, column select signals of more bits, e.g., 4-bit column select signals CSL<3:0> or 8-bit column select signals CSL<8:0>, may be employed. In the latter case of more column select signal bits, only the sense amplifier band for which column selection is carried out is activated, and consumed power can be reduced.

Furthermore, as for the arrangement of DRAM cells, even if DRAM cells are arranged in the manner of “quarter pitch arrangement” in which the length of bit line contacts adjacent in oblique direction projected in row direction is quarter a pitch of bit line contacts adjacent in this row direction, the present invention is applicable.

As stated so far, according to the present invention, only the sense amplifier band for which row access is performed is activated and the remaining sense amplifier bands are maintained in a precharge state, thereby making it possible to significantly reduce operational current.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory comprising:
a memory array having a plurality of memory cells arranged in rows and columns;
a plurality of word lines, arranged corresponding respective rows, each connecting to the memory cells on a corresponding row;
a plurality of bit lines arranged corresponding to the columns, having the memory cells on corresponding columns connected thereto, and arranged to form pairs; and
a row select circuit for driving a word line arranged corresponding to an addressed row into a select state in accordance with an address signal,
in said memory array, two memory cells being arranged per the two word lines and the two bit lines, and the two memory cells being so arranged as to be coupled to both of the bit lines in a pair by one selected word line.

2. The semiconductor memory according to claim 1, further comprising:
a plurality of sense amplifier circuits arranged corresponding to thed bit line pairs and differentially amplifying potentials of the bit lines of corresponding bit line pairs when being active, said plurality of sense amplifier circuits including a plurality of first sense amplifier circuits arranged on one side of said memory array and a plurality of second sense amplifier circuits arranged on an other side of said memory array; and
a sense control circuit activating either of the first and second sense amplifier circuits and holding the other sense amplifier circuits in an inactive state in response to said address signal and a sense amplifier activating signal.

3. The semiconductor memory according to claim 2, wherein
said plurality of bit line pairs include a first bit line pairs arranged corresponding to the first sense amplifier circuits, and second bit line pairs arranged corresponding to said second sense amplifier circuits; and wherein said semiconductor memory further comprises:
first bit line voltage holding circuits, arranged corresponding to the first bit line pairs, for holding corresponding first bit line pairs at a predetermined voltage level when active;
second bit line voltage holding circuits, arranged corresponding to the second bit line pairs, for holding corresponding second bit line pairs at said predetermined voltage level when active; and
bit line voltage control circuitry for setting either of the first and second bit line voltage holding circuits in an active state and setting other bit line voltage holding circuits in an inactive state in accordance with said address signal.

4. The semiconductor memory according to claim 3, wherein
said bit line voltage control circuitry sets the bit line voltage holding circuits, arranged corresponding to activated sense amplifier circuits out of the first and second sense amplifier circuits, in an inactive state, and maintains the bit line voltage holding circuits arranged corresponding to inactivated sense amplifier circuits in an active state, in accordance with said address signal.

5. The semiconductor memory according to claim 3, wherein
the bit line of the second bit line pair is arranged between each of the first bit line pairs, and the bit line of the first bit line pair is arranged between each of the second bit line pairs.

6. The semiconductor memory according to claim 2, wherein
said first sense amplifier circuits and said second sense amplifier circuits are alternately arranged in opposite on both sides of said memory array, respectively.

7. The semiconductor memory according to claim 1, wherein
each of the bit lines is arranged linearly along a column direction, and the bit line of another bit line pair is arranged between the bit lines in a pair.

8. A semiconductor memory comprising:
a plurality of memory arrays each having (i) a plurality of memory cells arranged in rows and columns, (ii) a plurality of word lines arranged corresponding to the rows and having the memory cells on corresponding rows connected thereto, and (iii) a plurality of bit lines arranged corresponding to the columns, having the memory cells on corresponding columns connected thereto, and arranged forming pairs, the bit lines arranged extending linearly along a column direction in corresponding memory arrays;
a row select circuit for driving a selected word line arranged corresponding to an addressed row into a select state in accordance with an address signal, the memory cells being arranged in each memory array such that two memory cells are arranged per two word lines and two bit lines and that the two memory cells are coupled to both bit lines in a pair by one selected word line;
a plurality of sense amplifier bands arranged among said plurality of memory arrays so as to be shared between adjacent memory arrays, each of said sense amplifier bands having a plurality of sense amplifier circuits, arranged corresponding to the bit line pairs in corresponding memory arrays, for differentially amplifying potentials of corresponding bit line pairs when being active;
a bit line isolation control circuit for, in accordance with said address signal, coupling the bit line pairs in a selected memory array including said selected word line to the sense amplifier circuits in a corresponding sense amplifier band, isolating a first memory array out of first and second memory arrays each sharing one sense amplifier band with said selected memory array, from a first sense amplifier band shared between said first memory array and said selected memory array, and coupling said second memory array to a second sense amplifier band shared between said second memory array and said selected memory array; and
a sense control circuit for activating the sense amplifier circuits in said first sense amplifier band, and holding the sense amplifier circuits in said second sense amplifier band to be in an inactive state, in accordance with said address signal.

9. The semiconductor memory according to claim 8, further comprising:
bit line voltage holding circuits, arranged corresponding to the bit line pairs, for holding corresponding bit line pairs at a predetermined voltage level when being active; and
a bit line voltage control circuit for activating the bit line voltage holding circuit arranged corresponding to the bit line pairs coupled to said second sense amplifier band, and inactivating the bit line voltage holding circuit arranged corresponding to the bit line pairs coupled to the sense amplifier circuits in said first sense amplifier band, in accordance with said address signal.

10. The semiconductor memory according to claim 8, wherein
in each of the memory arrays, said plurality of bit line pairs include first bit line pairs arranged corresponding to the sense amplifier circuits in either of corresponding two sense amplifier bands, and second bit line pairs arranged corresponding to the sense amplifier circuits in other sense amplifier band of the corresponding two sense amplifier bands, the bit line of the second bit line pair is arranged between the bit lines of each first bit line pair, and the bit line of the first bit line pair is arranged between each of said second bit line pairs.

11. The semiconductor memory according to claim 10, wherein
in said corresponding two sense amplifier bands, the sense amplifier circuits are alternately arranged oppositely along a row direction.

12. The semiconductor memory according to claim 8, further comprising:
a circuit for holding the bit line pairs coupled to the sense amplifier circuits in said second sense amplifier band at a predetermined voltage level.

13. The semiconductor memory according to claim 8, wherein
said row select circuit drives one word line into the select state in the selected memory array in accordance with said address signal.

14. The semiconductor memory according to claim 8, wherein
the memory cells are arranged such that layout units each constituted of 2-bit memory cells are arranged on every second column along a row direction in each column and the layout units are arranged to be staggered by two rows between adjacent columns.

15. The semiconductor memory according to claim 8, wherein
a row address signal designating a row of the memory cells in a memory array and a column address signal designating a column of the memory cells are applied concurrently, and
said row address signal is included in said address signal.

16. The semiconductor memory according to claim 1, wherein
the memory cells are arranged such that layout units each constituted of 2-bit memory cells are arranged on every second column along a row direction in each column and the layout units are arranged to be staggered by two rows between adjacent columns.

17. The semiconductor memory according to claim 1, wherein
a row address signal designating a row of the memory cells and a column address signal designating a column of the memory cells are applied concurrently, and
said address signal includes said address signal.
